(19) United States
(12) Patent Application Publication
(10) Pub. No.: US 2014/0030860 A1
(43) Pub. Date: Jan. 30, 2014

(54) MANUFACTURING METHOD OF TUNNEL OXIDE OF NOR FLASH MEMORY

(71) Applicants: YIDER WU, CHU-PEI CITY (TW); YI-HSIU CHEN, CHU-PEI CITY (TW); WEN-CHENG LEE, CHU-PEI CITY (TW)

(72) Inventors: YIDER WU, CHU-PEI CITY (TW); YI-HSIU CHEN, CHU-PEI CITY (TW); WEN-CHENG LEE, CHU-PEI CITY (TW)

(73) Assignee: EON SILICON SOLUTION, INC.

(21) Appl. No.: 13/556,490

(22) Filed: Jul. 24, 2012

(51) Int. Cl. H01L 21/336

(52) U.S. Cl. 438/264; 257/E21.423

(57) ABSTRACT

A manufacturing method of tunnel oxide of NOR flash memory controls the temperature and thickness of tunnel oxide in a gate structure to prevent a channel region to change its doping concentration and range due to a high-temperature manufacturing process, so as to overcome the leakage current and improve the reliability of storing data.

### FIELD OF TECHNOLOGY

The present invention relates to a manufacturing method of NOR flash memory, in particular to the manufacturing method of tunnel oxide of NOR flash memory.

### BACKGROUND

With reference to FIG. 1 for a NOR flash memory unit 100, a gate structure 110 is disposed on a semiconductor substrate 101, and the gate structure 110 from bottom to top comprises a tunnel oxide 111, a floating gate 113, a dielectric layer 115 having an ONO structure, and a control gate 117. The semiconductor substrate 101 on a side of the gate structure 110 includes a source region S and a drain region D, wherein a channel region 120 is formed in the semiconductor substrate 101 under the gate structure 110. A doping of the channel region 120 provides a delivery channel of electrons/electron holes between the source region S and the drain region D under a voltage control.

As the manufacturing technology of semiconductors and integrated circuits, the number of memory cells in a flash memory device becomes increasingly larger, and the size of the device is reduced continuously with the increased integrity, so that the positions of the memory units are very close to one another in the memory device, and the position of the channel region 120 is limited, or else the electrons/electron holes will be delivered unexpected to result in leakage current easily due to the error of the position of the channel region 120.

In the manufacturing method of the gate structure 110 of conventional memory devices, the process of manufacturing the tunnel oxide 111 is controlled at a high temperature above 900° C., and such high temperature condition will cause a diffusion of doping concentration in the channel region 120 and result in a defect such as a change of position of the channel region 120 or an expanded range, and this defect becomes increasingly more serious as the integrity increases. Therefore, as the channel length of the memory device decreases, the position of the channel region 120 becomes a key factor of producing a leakage current, and the leakage current of the memory device in the conventional method becomes a major issue as the integrity increases, and causes a low reliability of the device.

### SUMMARY

Therefore, it is a primary objective of the present invention to provide a NOR flash memory device with the property of a low leakage current so as to improve the reliability of data storage.

Another objective of the present invention is to maintain the doping depth and concentration in a channel region of a NOR flash memory.

To achieve the aforementioned and other objectives, the present invention provides a manufacturing method of tunnel oxide of a NOR flash memory, comprising the steps of: providing a semiconductor substrate; forming a channel region with a first doping in the semiconductor substrate; and growing the tunnel oxide on the semiconductor substrate at a temperature ranging from 650° C. to 800° C. until the tunnel oxide has a thickness falling within a range of 80 Å˜100 Å.

In a preferred embodiment, the tunnel oxide is formed by a wet air oxidization process.

In a preferred embodiment, the first doping has ions which are boron ions.

Therefore, the present invention can control the temperature and the thickness of the tunnel oxide to a specific range during the manufacturing process, so that the channel region will not have a change of the doping concentration and range due to the high-temperature manufacturing process, so as to overcome the problem of the leakage current and improve the reliability of data storage.

### BRIEF DESCRIPTION OF THE DRAWINGS

FIG. 1 is a schematic view of a NOR flash memory unit;

FIG. 2 is a flow chart of a manufacturing method of tunnel oxide of a NOR flash memory in accordance with a preferred embodiment of the present invention; and

FIGS. 3 to 6 are schematic views of structures at different steps of manufacturing tunnel oxide of a NOR flash memory in accordance with a preferred embodiment of the present invention.

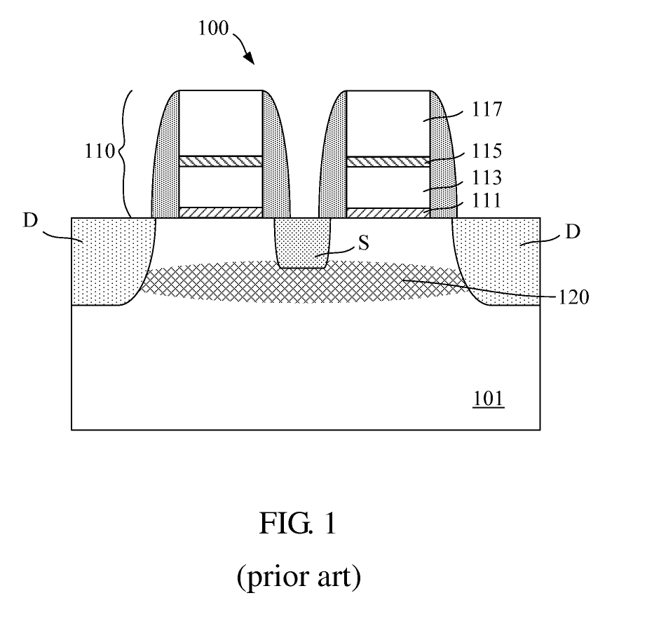

### DETAILED DESCRIPTION

The objects, characteristics and effects of the present invention will become apparent with the detailed description of the preferred embodiments and the illustration of related drawings as follows.

In a preferred embodiment of the present invention, the manufacturing process of tunnel oxide of a NOR flash memory gate structure is used to control the extent of diffusion of the channel region in the semiconductor substrate, so as to achieve the effect of controlling the doping concentration and range of the channel region.

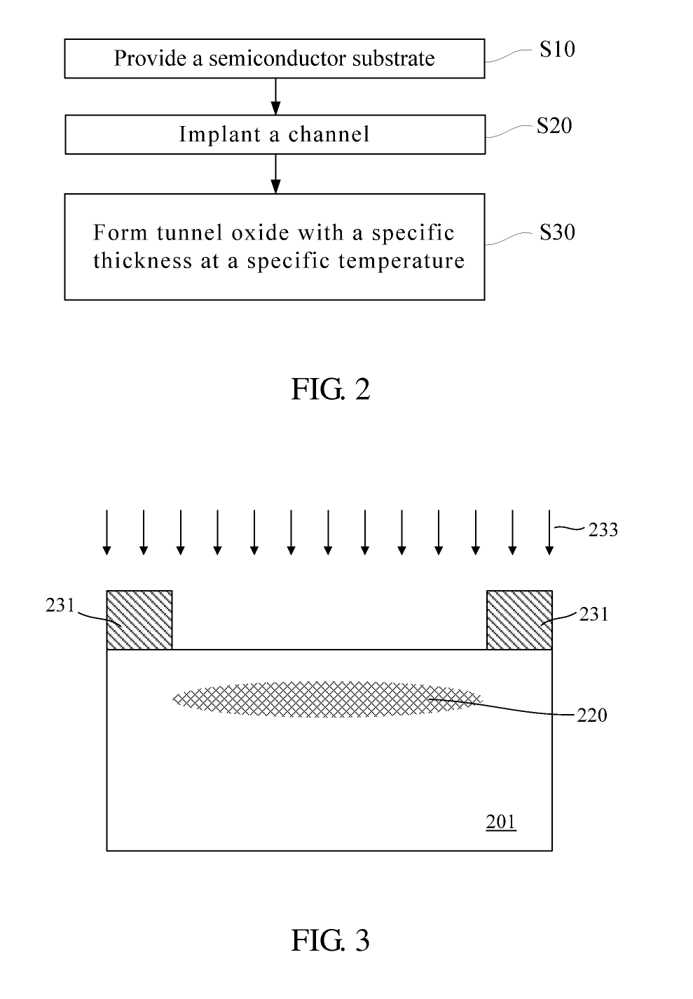

With reference to FIG. 2 for a flow chart of a manufacturing method of tunnel oxide of a NOR flash memory in accordance with a preferred embodiment of the present invention, the method comprises the following steps:

S10: Provide a semiconductor substrate, wherein the semiconductor substrate 100 is made of silicon, SiGe, silicon on insulator (SOI), silicon germanium on insulator (SGOI), or germanium on insulator (GOI).

S20: Perform an ion-implant manufacturing process to form a channel region having a first doping in the semiconductor substrate, wherein the first doping has ions which are boron ions such as boron difluoride (BF₂), and the implant conditions vary with different ions used, and the implant conditions are prior arts and thus will not be described here.

S30: Form tunnel oxide in a gate structure at a specific temperature. Since the conventional manufacturing process is a manufacturing process generally performed at a high temperature over 900° C., and the high temperature may cause the diffusion of the range of the implanted channel region easily to change the originally expected size range and position of the channel region and result in the occurrence of a leakage current. Therefore, the temperature of manufacturing the tunnel oxide is controlled to a temperature ranging from 650° C. to 800° C. in this preferred embodiment of the present invention, and the thickness of the tunnel oxide grown on the semiconductor substrate within this specific range of temperature falls within a range of 80 Å˜100 Å.

In a preferred embodiment, the tunnel oxide is formed by a wet air oxidization process. For example, the reaction of the wet air oxidization process is given below:

Si(s)+2H₂O(g)→SiO₂(s)+2H₂(g) (Formula 1)

Wherein, the oxidation reaction shown in Formula 1 relates to water molecules. Although most water molecules exist in a gaseous form, yet it is common to call the process as a wet air oxidization process.

With reference to FIGS. 3 to 6 for schematic views of structures at different steps of manufacturing tunnel oxide of a NOR flash memory in accordance with a preferred embodiment of the present invention respectively, and FIG. 2 for the flow chart of the manufacturing method, a photoresist 231 or any other equivalent device are used as a shield of the semiconductor substrate 201 depicted in FIG. 3, and then the ion-implant manufacturing process 233 is performed to form a channel region 220 in the semiconductor substrate 201.

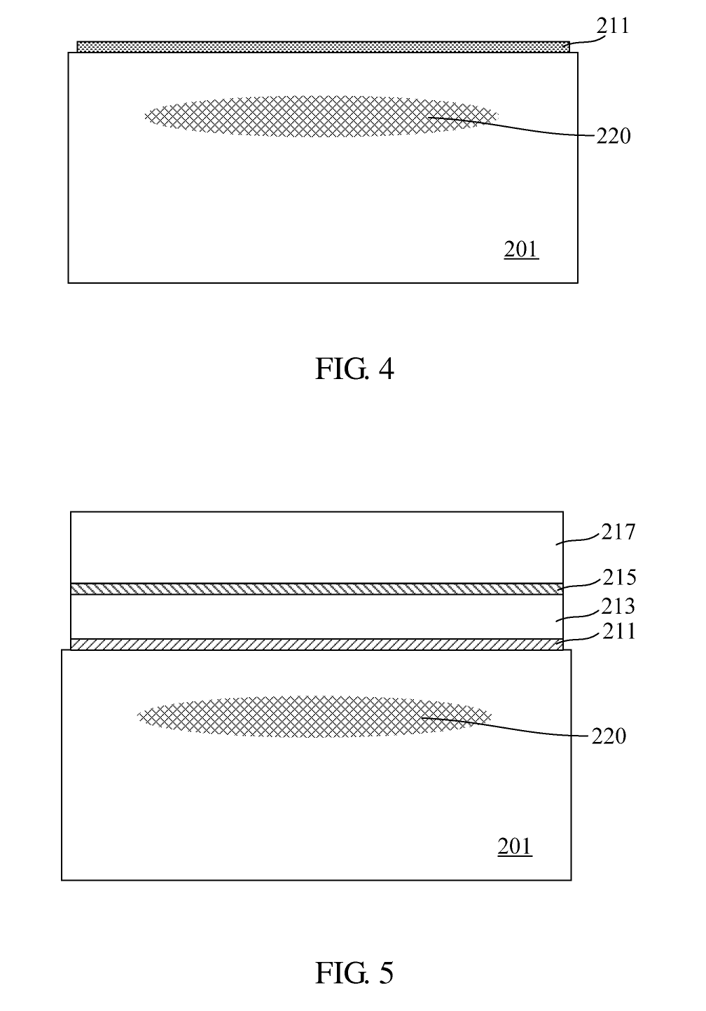

In FIG. 4, the tunnel oxide 211 is grown at a temperature of 650° C. to 800° C. to a thickness of approximately 80 Å˜100Å after the photoresist 231 is removed, and the growing time is determined by the temperature of the process and the thickness of the tunnel oxide 211.

In FIG. 5, a floating gate 213, a dielectric layer 215 having an ONO structure, and a control gate 217 are formed sequentially on the tunnel oxide 211.

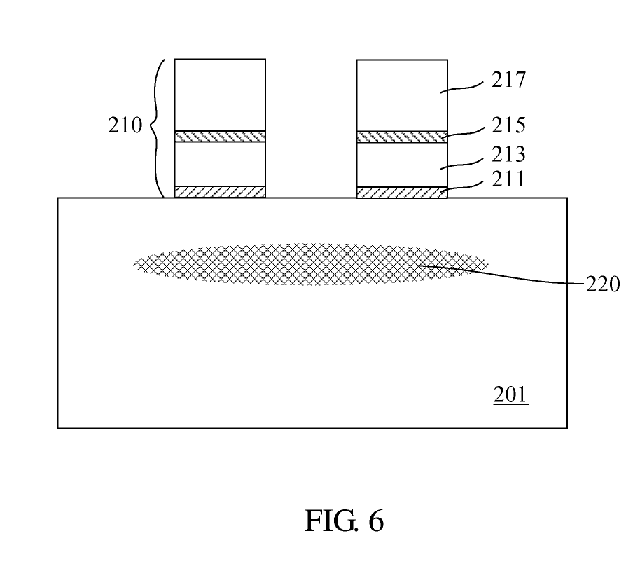

FIG. 6 shows a portion of the gate structure 210 obtained after the etching process. The process of implanting a source and a drain takes place. This process is a prior art, and thus will not be described.

In summation of the description above, the manufacturing process in accordance with the foregoing preferred embodiment of the present invention can provide a better leaking current resisting effect of the NOR flash memory to reduce the chance of having a punch-through leakage of non-conducted components, so as to improve the reliability of memory devices.

While the invention has been described by means of specific embodiments, numerous modifications and variations could be made thereto by those skilled in the art without departing from the scope and spirit of the invention set forth in the claims.

What is claimed is:

1. A manufacturing method of tunnel oxide of NOR flash memory, comprising the steps of:
providing a semiconductor substrate;
forming a channel region with a first doping in the semiconductor substrate; and
growing the tunnel oxide on the semiconductor substrate at a temperature ranging from 650° C. to 800° C. until the tunnel oxide has a thickness falling within a range of 80 Å˜100 Å.

2. The manufacturing method of claim 1, wherein the tunnel oxide is formed by a wet air oxidization process.

3. The manufacturing method of claim 1, wherein the first doping has ions which are boron ions.
